(19) United States
(12) Patent Application Publication
(10) Pub. No.: US 2019/0006202 A1
(43) Pub. Date: Jan. 3, 2019

(54) REPAIRING APPARATUS FOR REMOVAL OF METAL RESIDUALS ON DISPLAY SUBSTRATE

(71) Applicants: BOE Technology Group Co., Ltd., Beijing (CN); Hefei Xinsheng Optoelectronics Technology Co., Ltd., Hefei (CN)

(72) Inventors: Qi Yin, Beijing (CN); Yonghui Wang, Beijing (CN); Qingchao Meng, Beijing (CN); Dai Dong, Beijing (CN); Zongyi Chen, Beijing (CN)

(21) Appl. No.: 15/943,407

(22) Filed: Apr. 2, 2018

(30) Foreign Application Priority Data
Jul. 3, 2017 (CN) 201720797587.2

(51) Int. Cl. H01L 21/67; H01L 21/02; H01L 27/12

(52) U.S. Cl. CPC H01L 21/67017; H01L 21/02041; H01L 27/12; H01L 21/02334

(57) ABSTRACT

A repairing apparatus for removal of metal residuals on a display substrate is provided. The apparatus includes a storage container, comprising at least a first container configured to store a metal etchant; an adsorption component, configured to be adsorbed on a surface to be repaired on the display substrate and to cooperate with the surface to be repaired to define collectively a closed chamber therebetween; and a circulating pipe assembly, arranged to be connected and in fluid communication between the storage container and the adsorption component. The repairing apparatus may include a first fluid circuit arranged to be connected and in fluid communication between the first container and the adsorption component and configured to guide the metal etchant within the first container to flow to the adsorption component and into the chamber and then back into the first container.

### CROSS-REFERENCE TO RELATED APPLICATION

The present disclosure claims the benefit of Chinese Patent Application Disclosure No. 201720797587.2 filed on Jul. 3, 2017 in the State Intellectual Property Office of China, the whole disclosure of which is incorporated herein by reference.

### TECHNICAL FIELD

Embodiments of the present disclosure relate to the technical field of display devices, and in particular to a repairing apparatus for the removal of metal residuals on a display substrate.

### BACKGROUND

In processes for manufacturing a display substrate, after cleaning the display substrate by a metal etchant (i.e., a corrosive liquid for removal of metallic material), there may still be some metal residues left on the display panel, which may not only impose an adverse effect on electrical properties of the display substrate but also result in an appearance problem of the display substrate due to an existence of these metal residues of relatively large sizes (e.g. diameter) on the display substrate. As to metal residues of relatively large sizes, a repairment for the display substrate is typically carried out by laser in relevant technologies, at a speed in repairment depending on a scanning speed of the laser, and fails to implement a successful repairment by removal of metal residues left at an active area on a display device. This is due to the fact that, in case that the active area is repaired by removal of metal residues thereon with laser, then an ITO layer beneath metal film layer(s) may be influenced adversely by laser, and the appearance of the display substrate thus formed may in turn be influenced adversely.

### SUMMARY

The embodiments of the present disclosure have been made to overcome or alleviate at least one aspect of the above mentioned disadvantages and/or shortcomings in the prior art, by providing a repairing apparatus for removal of metal residuals on a display substrate as below.

The following technical solutions are adopted in exemplary embodiments of the disclosure for achieving the above desired technical purposes.

According to an aspect of the exemplary embodiment of the present disclosure, there is provided a repairing apparatus for removal of metal residuals on a display substrate, comprising: a storage container, comprising at least a first container configured to store a metal etchant; an adsorption component, configured to be adsorbed on a surface to be repaired on the display substrate and to cooperate with the surface to be repaired to define collectively a closed chamber therebetween; and a circulating pipe assembly, arranged to be connected and in fluid communication between the storage container and the adsorption component, and comprising a first fluid circuit which is arranged to be connected and in fluid communication between the first container and the adsorption component and configured to guide the metal etchant accommodated within the first container to flow to the adsorption component and into the chamber and then to flow back into the first container.

In an embodiment of the disclosure, the storage container further comprises a second container configured to store a cleaning solution, and the circulating pipe assembly further comprises a second fluid circuit which is arranged to be connected and in fluid communication between the second container and the adsorption component and configured to guide the cleaning solution accommodated within the second container to flow to the adsorption component and into the chamber and then to flow back into the second container.

In an embodiment of the disclosure, the first fluid circuit comprises a first pipe and a second pipe; the first pipe is connected and in fluid communication at an end thereof with the first container, and is also connected and in fluid communication at the other end thereof with the adsorption component, with the other end thereof being in fluid communication with the chamber and configured to be an inlet port for the metal etchant; and the second pipe is connected and in fluid communication at an end thereof with the adsorption component, with the end thereof being in fluid communication with the chamber and configured to be an outlet port for the metal etchant, and is also connected and in fluid communication at the other end thereof with the first container.

In an embodiment of the disclosure, the inlet port for the metal etchant is located at a level higher than the outlet port for the metal etchant, within the chamber.

In an embodiment of the disclosure, the second fluid circuit comprises a third pipe and a fourth pipe; the third pipe is connected and in fluid communication at an end thereof with the second container, and is also connected and in fluid communication at the other end thereof with the adsorption component, with the other end thereof being in fluid communication with the chamber and configured to be an inlet port for the cleaning solution; and the fourth pipe is connected and in fluid communication at an end thereof with the adsorption component, with the end thereof being in fluid communication with the chamber and configured to be an outlet port for the cleaning solution, and is also connected and in fluid communication at the other end thereof with the second container.

In an embodiment of the disclosure, the inlet port for the cleaning solution is located at a level higher than the outlet port for the cleaning solution, within the chamber.

In an embodiment of the disclosure, the repairing apparatus further comprises a movable assembly, on which the adsorption component is provided, the movable assembly comprising: a movable table, on which a first travel rail is formed, the first travel rail is arranged to extend in a first direction of the movable table; and a movable support, which is provided at an upper portion thereof with the adsorption component, and is in slidable connection at an lower portion thereof with the first travel rail.

In an embodiment of the disclosure, the movable support comprises: a rod body on which the adsorption component is provided; and a second travel rail arranged to extend in a second direction at an angle with respect to the first travel rail, the rod body being in slidable connection with the second travel rail, and the second travel rail being in slidable connection at a bottom portion thereof with the first travel rail.

In an embodiment of the disclosure, the movable assembly further comprises an image acquisition device provided on the movable support.

In an embodiment of the disclosure, the repairing apparatus further comprises a drive component which is arranged to be connected electrically with the movable assembly and configured to control the movable assembly to move in the first direction.

In an embodiment of the disclosure, the repairing apparatus further comprises a fixation table configured to fix the display substrate, with at least one fixation component being provided on the fixation table and configured to fix the display substrate.

In an embodiment of the disclosure, the at least one fixation component comprises a plurality of the adsorption components.

In an embodiment of the disclosure, the drive component is further configured to control the movable assembly to move in the second direction.

In an embodiment of the disclosure, the first direction is substantially perpendicular to the second direction.

In an embodiment of the disclosure, the first direction is a lengthwise direction of the movable table.

In an embodiment of the disclosure, the adsorption component is a suction disc.

It is understood that other embodiments and configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### BRIEF DESCRIPTION OF THE DRAWINGS

The above and other features and advantages of the present disclosure will become more apparent and a more comprehensive understanding of the present disclosure can be obtained, by describing in detail exemplary embodiments thereof with reference to the accompanying drawings, in which:

FIG. 1 illustrates a structural schematic view of a repairing apparatus for removal of metal residuals on a display substrate according to an embodiment of the disclosure;

FIG. 2 illustrates a sectional structural schematic view of an adsorption component according to another embodiment of the disclosure;

FIG. 3 illustrates a structural schematic view of a repairing apparatus for removal of metal residuals on a display substrate according to yet another embodiment of the disclosure.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms, and thus the detailed description of the embodiment of the disclosure in view of attached drawings should not be construed as being limited to the embodiment set forth herein; rather, these embodiments are provided so that the present disclosure will be thorough and complete, and will fully convey the general concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In combination with embodiments of the disclosure as set forth hereinafter, a repairing apparatus for removal of metal residuals on a display substrate is provided herein, which apparatus may clean metal residues on the display substrate directly, without imposing any other influence on appearance of the active area of the display substrate, and being characterized in a convenient and effective repairment brought about thereby.

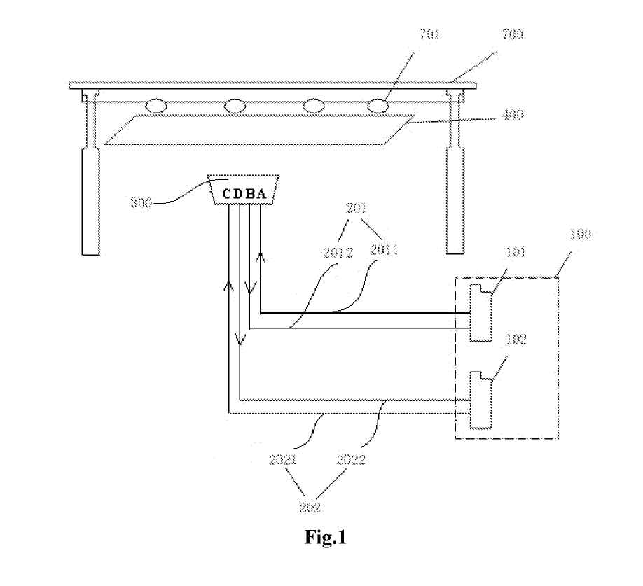

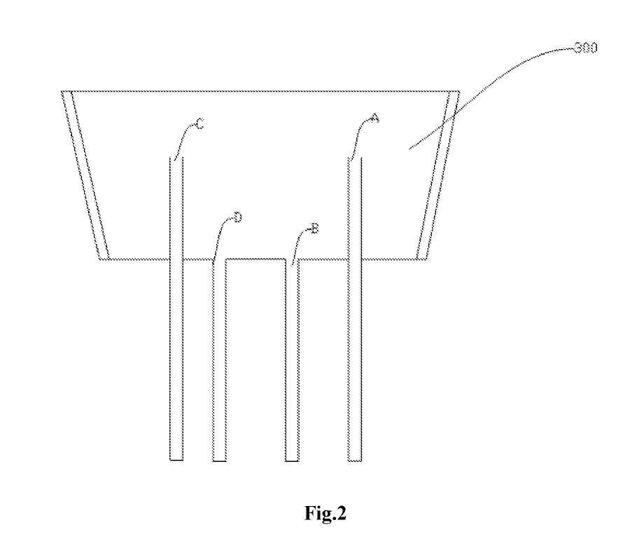

As illustrated in FIG. 1, it illustrates a structural schematic view of a repairing apparatus for removal of metal residuals on a display substrate according to an embodiment of the disclosure. And as illustrated in FIG. 2, it illustrates a structural schematic view of an adsorption component according to an embodiment of the disclosure.

The repairing apparatus for removal of metal residuals on a display substrate is provided in embodiments of the disclosure, which is convenient in repairment without imposing any effect on a display panel. According to a general technical concept of embodiments of the present disclosure, for example, the repairing apparatus for removal of metal residuals on a display substrate comprises: a storage container 100, an adsorption component 300, and a circulating pipe assembly connected between the storage container 100 and the adsorption component 300.

The storage container 100 for example comprises a first container 101 configured to store a metal etchant. The first container 101 is for example constructed to be a container of any shape and structure which is applicable to store the metal etchant, without being limited in embodiments of the disclosure. Moreover, the first container is manufactured by a material which is chosen to be a material resist to any corrosion by the metal etchant.

Furthermore, the adsorption component 300 is for example a suction disc, and is configured to be adsorbed onto a surface to be repaired on the display substrate; and in a condition that the adsorption component 300 is adsorbed on the surface to be repaired on the display substrate 400, it fits and cooperates with the surface to be repaired on the display substrate so as to define collectively a closed (e.g., hollow) chamber therebetween, the chamber being for example a liquid-tight one, i.e., the fluid therein may not escape therefrom to opened external environment. The chamber is configured to accommodate the metal etchant delivered through the circulating pipe assembly, and to clean off the metal residues on the display substrate 400.

The circulating pipe assembly is for example arranged to be connected and in fluid communication between the storage container 100 and the adsorption component 300, and comprises at least a first fluid circuit 201 which is configured to guide the metal etchant accommodated within the first container 101 to flow to the adsorption component 300 and into the chamber and then to flow back into the first container 101. Specifically, the first fluid circuit 201 for example comprises a first pipe 2011 and a second pipe 2012 which are connected and in fluid communication between the first container 101 and the adsorption component 300. The first pipe 2011 is configured to guide the metal etchant accommodated within the first container 101 to flow to the adsorption component 300 and into the chamber; and the second pipe 2012 is configured to guide the metal etchant already guided to the adsorption component 300 to flow back into the first container 101. As such, the first pipe 2011 and the second pipe 2012 cooperate with each other to form collectively a circulating channel for the metal etchant.

Specifically, as illustrated in FIG. 2, the first pipe 2011 is arranged to be connected and in fluid communication at an end thereof with the first container 101, and is also connected and in fluid communication at the other end thereof with the adsorption component 300, with the other end thereof being configured to be an inlet port A for the metal etchant in fluid communication with the chamber; and the second pipe 2012 is arranged to be connected and in fluid communication at an end thereof with the adsorption component 300, with the end thereof being configured to be an outlet port B for the metal etchant in fluid communication with the chamber, and is also connected and in fluid communication at the other end thereof with the first container. That is to say, the metal etchant stored within the first container 101 may be delivered to the adsorption component 300, through the first fluid circuit 201, and the chamber defined collectively by both the adsorption component 300 and the display substrate 400 may then be used to store a certain amount of the metal etchant for cleaning off the metal residues left on the display substrate 400; meanwhile, the first fluid circuit 201 is for example further configured to guide the metal etchant to flow out of the chamber and then to flow back into the first container 101. In other words, the metal etchant within the first fluid circuit 201 may circulate between the first container and the adsorption component, so as to avoid any waste of the metal etchant, and also to prevent any harm to any other devices or human bodies caused by outflow of the metal etchant to ambient environment and thus lead to a superior security effect.

Moreover, in further embodiments of the disclosure, in the first fluid circuit 201, the end of the first pipe 2011 functioning as the inlet port A for the metal etchant is located at a level higher than the other end of the second pipe 2012 functioning as the outlet port B for the metal etchant, within the chamber. Therefore, once the repairment is completed, the metal etchant left within the chamber of the adsorption component 300 may flow into the second pipe 2012 persistently under the action of gravity thereof, until the metal etchant is evacuated completely from the chamber, preventing any metal etchant from remaining within the adsorption component 300 once the repairment is completed, and also facilitating a circulation flow of the metal etchant effectively. By way of example, a first valve body or first valve bodies may be provided additionally on the first pipe 2011 and/or the second pipe 2012 of the first fluid circuit 201, facilitating adjustment on both inflow and outflow of the metal etchant. Furthermore, a first pump may also for example be provided additionally, which is configured to pump the metal etchant from inside the first container to the circulating pipe assembly.

In addition, in embodiments of the disclosure, as illustrated in FIG. 1, in order to further ensure stability and robustness of the display substrate 400, the apparatus for example comprises a fixation table 700 configured to fix the display substrate 400, with at least one fixation component being provided on the fixation table and configured to fix the display substrate 400. For example, said at least fixation component 701 may for example be a plurality of fixation clamps which are provided on the fixation table and configured to fix the display substrate 300, and may alternatively be a plurality of the adsorption components as illustrated in FIG. 1, or fixation components in any other form(s).

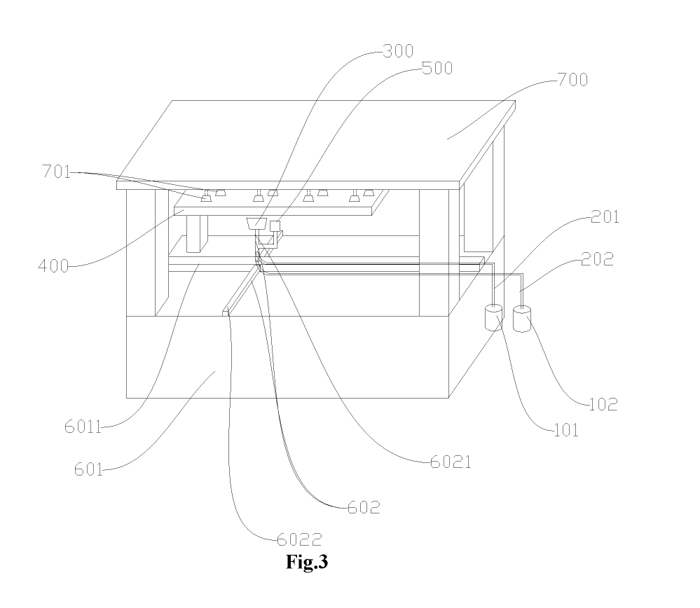

In addition, in embodiments of the disclosure, in order to determine locations of the metal residues on the display substrate 400, the apparatus is for example further provided with an image acquisition device 500 (as illustrated in FIG. 3) configured to capture image(s) of the surface to be repaired on the display substrate 400. Once the images are captured thereby, and then locations to be repaired on the surface to be repaired at which locations there exist metal residues may be determined depending on the captured images. Next, the adsorption component 300 is adsorbed onto the locations to be repaired, so as to implement in turn repairment operations for the metal residues left on the surface to be repaired.

In embodiments of the disclosure with above configuration(s), during repairment of the display substrate 400, for example, the adsorption component 300 is adsorbed onto locations to be repaired on the surface to be repaired on the display substrate 400, at which locations there exist metal residues, and then the metal etchant is brought into the adsorption component 300 through the first pipe 2011 of the first fluid circuit 201 by adjusting the valve body or bodies on the first fluid circuit 201 (there may be valve bodies provided on both the first pipe 2011 and the second pipe 2012, facilitating control on flow of the metal etchant), and then a portion of the incoming metal etchant is stored within the chamber defined collectively by both the adsorption component 300 and the display substrate 400 for repairment of the display substrate. Meanwhile, the metal etchant within the chamber of the adsorption component 300 for example flow back through the second pipe 2012 into the first container 101 so as to form a complete circulation flow of the metal etchant. Such a whole process of circulation may for example last several minutes, and then be terminated by closing the valve body or bodies on the first fluid circuit. Above processes may facilitate implementation of repairment by elimination of metal residues on the surface to be repaired on the display substrate, only if the adsorption component is adsorbed onto the locations on the surface to be repaired on the display substrate 400 at which locations there exist metal residues; in other words, by cleaning off/eliminating the metal residues by the metal etchant introduced from inside the storage container 100 (specifically, from inside the first container 101 within the storage container 100), a convenient cleaning of the metal substrate may be implemented.

Moreover, in embodiments of the disclosure, in addition to aforementioned first container 101 for storing metal etchant, the storage container 100 for example comprises a second container 102 configured to store a cleaning solution. The first container 101 and the second container 102 for example are two containers separated and independent from each other; or alternatively, the storage container 100 is divided by a spacer provided therein, into these two containers spaced apart from and independent from each other, without being limited in embodiments of the disclosure. Furthermore, the cleaning solution within the second container 102 may for example be water, or for example be any other cleaning liquid which may be used to clean/rinse the display substrate 400 (e.g., after the display substrate is flushed by the metal etchant) and/or chamber 300.

Moreover, the circulating pipe assembly for example further comprises a second fluid circuit 202 configured to guide the cleaning solution within the second container 102 to the adsorption component for cleaning operation. Specifically, the second fluid circuit 202 is for example configured to guide the cleaning solution accommodated within the second container 102 to flow to the adsorption component 300 and into the chamber and then to flow back into the second container 102. Specifically, the second fluid circuit 202 for example comprises a third pipe 2021 and a fourth pipe 2022 which are connected and in fluid communication between the second container 102 and the adsorption component 300.

The third pipe 2021 is configured to guide the cleaning solution accommodated within the second container 102 to flow to the adsorption component 300 and into the chamber; and the fourth pipe 2022 is configured to guide the cleaning solution already guided to the adsorption component 300 to flow therefrom and back into the second container 102. As such, the third pipe 2021 and the fourth pipe 2022 cooperate with each other to form collectively a circulating channel for the cleaning solution.

Specifically, as illustrated in FIG. 2, the third pipe 2021 is arranged to be connected and in fluid communication at an end thereof with the second container 102, and is also connected and in fluid communication at the other end thereof with the adsorption component 300, with the other end thereof being in fluid communication with the chamber and configured to be an inlet port C for the cleaning solution; and the fourth pipe 2022 is arranged to be connected and in fluid communication at an end thereof with the adsorption component 300, with the end thereof being in fluid communication with the chamber and configured to be an outlet port D for the cleaning solution, and is also connected and in fluid communication at the other end thereof with the second container 102. That is to say, the cleaning solution stored within the second container 102 may be delivered to the adsorption component 300, through the second fluid circuit 202, and the chamber defined collectively by both the adsorption component 300 and the display substrate 400 may then be used to store a certain amount of the cleaning solution for cleaning off the metal etchant (and metal residues, if any) e.g., left in the chamber; meanwhile, the second fluid circuit 202 is for example further configured to guide the cleaning solution to flow out of the chamber and then to flow back into the second container 102. In other words, the cleaning solution within the second fluid circuit 202 may circulate between the second container 202 and the adsorption component 300, so as to avoid any waste of the cleaning solution, and also to remove residual metal etchant from the adsorption component 300 effectively by cleaning/rinsing therefrom.

Moreover, in further embodiments of the disclosure, in the second fluid circuit 202, the end of the third pipe 2021 functioning as the inlet port C for the cleaning solution is located at a level higher than the other end of the fourth pipe 2022 functioning as the outlet port D for the cleaning solution, within the chamber. Therefore, once the rinsing by the metal etchant is completed, portions of the metal etchant (which metal etchant was once left on the display substrate 400 and/or within the adsorption component 300) still remaining within the adsorption component 300 may flow into (the fourth pipe 2022 of) the second fluid circuit 202 persistently out of the outlet port D with the outflow of the cleaning solution, under the action of gravity thereof and with the action applied by flushing by the cleaning solution, until all metal etchant remaining within the chamber is evacuated, also facilitating a circulation flow of the cleaning solution (e.g., carrying therewith the metal etchant). By way of example, a second valve body or second valve bodies may be provided additionally on the third pipe 2021 and/or the fourth pipe 2022, facilitating adjustment on both inflow and outflow of the cleaning solution and the metal etchant carried therewith. Furthermore, a second pump may also for example be provided additionally, which is configured to pump the cleaning solution from inside the second container to the circulating pipe assembly.

Base on above embodiments, for example, after the display substrate 400 is repaired by the metal etchant within the first container 101, the first valve body or bodies may be shut off, and the second valve body or bodies provided on the second fluid circuit 202 may then be opened (the second valve body or bodies may for example be provided on both the third pipe 2021 and the fourth pipe 2022), such that the cleaning solution within the second container 102 may flow into the adsorption component 300 through the third pipe 2021, and corresponding locations on the display substrate and/or within the chamber at which there exist residual metal etchant may be cleaned/rinsed; meanwhile, the cleaning solution may also flow back to the second container 102 through the fourth pipe 2022, facilitating implementation of cleaning operation for the residual metal etchant on the display substrate and within the chamber.

In addition, as illustrated in FIG. 3, it illustrates a structural schematic view of the repairing apparatus for removal of metal residuals on a display substrate according to yet another embodiment of the disclosure. On the basis of above embodiments, for example, the apparatus further comprises a movable assembly which is configured to drive the adsorption component to displace. The adsorption component 300 is for example provided on the movable assembly. And the movable assembly for example comprises: a movable table 601, and a movable support 602 which is provided in slidable connection with the movable table 601. In specific embodiments, by way of example, on the movable table 601, there is provided a first travel rail 6011 which for example extends in a longitudinal direction of the movable table 601 (i.e., a lengthwise direction thereof) as illustrated, and the movable support 602 is in slidable connection at a lower portion thereof with the first travel rail 6011 and is also provided at an upper portion thereof with the adsorption component 300, such that the adsorption component 300 may be moved relative to the movable table 601 by a relative sliding motion of the movable support 602 on the movable table 601 (e.g., on the first travel rail 6011 thereof) so as to change specific position of the adsorption component 300 relative to the movable table 601. Furthermore, by way of example, on the movable table 601, there are provided a plurality of first travel rails 6011, so as to facilitate adjustment of the position of the adsorption component. Above slidable connection between the movable table 601 and the movable support 602 may for example be implemented by a pulley, or by other means.

In embodiments of the disclosure, for example, the movable support 602 is also constructed to be a slidable support, which specifically comprises: a rod body 6021 on which the adsorption component 300 is provided/mounted, and a second travel rail. The rod body 6021 is arranged vertically and configured to slide along the second travel rail 6022 which extends in a direction at an angle with respect to the first travel rail 6021, and the second travel rail 6022 is arranged to intersect at a bottom portion thereof with the first travel rail 6011 such that there are in a slidable connection with each other.

In order to adjust specific position of the adsorption component 300 in a more omni-directional manner, in embodiments of the disclosure, above first travel rail 6011 is for example a travel rail provided in a first direction of the movable table 601 (i.e., the lengthwise direction of the movable table), and the second travel rail is for example another travel rail formed to extend in a second direction at an angle with respect to the first direction. The first direction and the second direction are for example two directions perpendicular to each other. Therefore, the adsorption component may not only move in the first direction but also in the second direction, such that the repairment of the display substrate 400 may be implemented more conveniently and in a more omni-directionally manner by flushing by the metal etchant.

In addition, in embodiments of the disclosure, for example, the movable assembly further comprises aforementioned image acquisition device 500 provided on the movable support 602, such as CCD sensor, CMOS sensor, and the like, so as to capture the image(s) of the surface to be repaired on the display substrate 400, and image(s) of position and/or motion track of the adsorption component 300 in motion.

Based on above configurations, in embodiments of the disclosure, it may be convenient to move the adsorption component to the location(s) to be repaired on the surface to be repaired, such a movement may for example be implemented specifically by movement of the movable support and the movable table in the first direction, and movement of the movable rod and the second travel rail in the second direction; in other words, the movement of the adsorption component may be considered to be implemented equivalently by establishing at least one rectangular plane coordinate system, such that the movement along both coordinate axes of the rectangular plane coordinate system may cover various locations across the whole movable table, facilitating an omni-directional movement of the adsorption component 300 on the surface to be repaired on the display substrate 400, and a fast and convenient positioning of the adsorption component to the locations to be repaired on the surface to be repaired.

Furthermore, in an embodiment of the disclosure, the apparatus further comprises a drive component which is configured to drive the movable support 602 to slide in the first direction and to drive the rod body 6021 to move in the second direction. In a more specific embodiment of the disclosure, the drive component for example comprises a controller, and a drive motor connected electrically with the controller, as well as a transmission assembly connected between the drive motor and the movable support 602. By way of example, the controller is configured to transmit towards the drive motor a first control signal which instructs/controls the movable assembly to move over a first amount of movement in the first direction, and/or a second control signal which instructs/controls the rod body to move over a second amount of movement in the second direction, and the drive motor is configured to drive the transmission assembly to move over its own amount of movement corresponding to the first amount of movement by the movable assembly and the second amount of movement by the rod body respectively once the drive motor receives aforementioned first and second control signals, e.g., depending on specific instruction(s) of the first control signal or the second control signal correspondingly. For example, above transmission assembly comprises: a drive screw, a transmission gear train, and the like.

In addition, aforementioned first control signal and second control signal formed by the controller are for example obtained on the basis of the images captured by the image acquisition device 500, and/or also for example signals received from other electronic apparatus(es).

In the image acquisition device 500, for example, there is provided a camera and a communication module in communicative connection with the camera, the communication module comprising a Bluetooth module, a Wi-Fi module, and the like. Therefore, the communication module which is well-configured may transmit image information captured by the camera to a display apparatus connected therewith for displaying. Then, relevant information (for example, the amount of movement in the first direction and the amount of movement in the second direction starting from current position each of which should be implemented so as to position the adsorption component 300 to the location(s) to be repaired), which relates to locations to be repaired on the surface to be repaired on the present display substrate at which locations there still exist metal residues, may become known depending on the images as captured. Above information concerning position/location is for example represented by coordinate values in the coordinate system. And then the controller receives such information and generates the first control signal and the second control signal corresponding thereto, so as to drive the drive assembly and the rod body to the corresponding locations to be repaired. With above configuration, the apparatus as provided in embodiments of the disclosure may become even more intelligent and more convenient in operation thereof, as compared with relevant technologies. It should be noticed that, both the control and the drive on the movable support by the controller may be implemented by relevant technical means, without any limitation and protection being applied on specific method(s) for implementing above functionalities by embodiments of the disclosure in.

As compared with relevant technologies, there are at least some beneficial technical effects brought about by the technical solutions provided by the embodiments of the disclosure, as follows:

In conclusion, the repairing apparatus for removal of metal residuals on a display substrate as provided in embodiments of the disclosure may repair the display substrate by removal of metal residues thereon conveniently, without bringing about any other additional adverse influence on appearance of the display substrate; therefore, it may be used to implement a repairment on Active Area of the display substrate. In addition, it may also be characterized by a convenient operation thereof and a superior repairment effect brought about thereby.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although the disclosure is described in view of the attached drawings, the embodiments disclosed in the drawings are only intended to illustrate the preferable embodiment of the present disclosure exemplarily, and should not be deemed as a restriction thereof.

Although several exemplary embodiments of the general concept of the present disclosure have been shown and described, it would be appreciated by those skilled in the art that various changes or modifications may be made in these embodiments without departing from the principles and spirit of the disclosure and lie within the scope of present application, which scope is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A repairing apparatus for removal of metal residuals on a display substrate, comprising:
a storage container, comprising at least a first container configured to store a metal etchant;
an adsorption component, configured to be adsorbed on a surface to be repaired on the display substrate and to cooperate with the surface to be repaired to define collectively a closed chamber therebetween; and
a circulating pipe assembly, arranged to be connected and in fluid communication between the storage container and the adsorption component, and comprising a first fluid circuit which is arranged to be connected and in fluid communication between the first container and the adsorption component and configured to guide the metal etchant accommodated within the first container to flow to the adsorption component and into the closed chamber and then to flow back into the first container.

2. The repairing apparatus according to claim 1, wherein the storage container further comprises a second container configured to store a cleaning solution, and the circulating pipe assembly further comprises a second fluid circuit which is arranged to be connected and in fluid communication between the second container and the adsorption component and configured to guide the cleaning solution accommodated within the second container to flow to the adsorption component and into the chamber and then to flow back through the adsorption component into the second container.

3. The repairing apparatus according to claim 1, wherein the first fluid circuit comprises a first pipe and a second pipe;
wherein the first pipe is connected and in fluid communication at an end thereof with the first container, and is also connected and in fluid communication at the other end thereof with the adsorption component, with the other end thereof being in fluid communication with the chamber and configured to be an inlet port for the metal etchant; and
wherein the second pipe is connected and in fluid communication at an end thereof with the adsorption component, with the end thereof being in fluid communication with the chamber and configured to be an outlet port for the metal etchant, and is also connected and in fluid communication at the other end thereof with the first container.

4. The repairing apparatus according to claim 3, wherein the inlet port for the metal etchant is located at a level higher than the outlet port for the metal etchant, within the chamber.

5. The repairing apparatus according to claim 3, wherein the storage container further comprises a second container configured to store a cleaning solution, and the circulating pipe assembly further comprises a second fluid circuit which is arranged to be connected and in fluid communication between the second container and the adsorption component and configured to guide the cleaning solution accommodated within the second container to flow to the adsorption component and into the chamber and then to flow back through the adsorption component into the second container.

6. The repairing apparatus according to claim 5, wherein the second fluid circuit comprises a third pipe and a fourth pipe;
wherein the third pipe is connected and in fluid communication at an end thereof with the second container, and is also connected and in fluid communication at the other end thereof with the adsorption component, with the other end thereof being in fluid communication with the chamber and configured to be an inlet port for the cleaning solution; and
wherein the fourth pipe is connected and in fluid communication at an end thereof with the adsorption component, with the end thereof being in fluid communication with the chamber and configured to be an outlet port for the cleaning solution, and is also connected and in fluid communication at the other end thereof with the second container.

7. The repairing apparatus according to claim 6, wherein the inlet port for the cleaning solution is located at a level higher than the outlet port for the cleaning solution, within the chamber.

8. The repairing apparatus according to claim 1, further comprising a movable assembly, on which the adsorption component is provided, the movable assembly comprising:
a movable table, on which a first travel rail is formed, the first travel rail is arranged to extend in a first direction of the movable table; and
a movable support, which is provided at an upper portion thereof with the adsorption component, and is in slidable connection at an lower portion thereof with the first travel rail.

9. The repairing apparatus according to claim 8, wherein the movable support comprises:
a rod body on which the adsorption component is provided; and
a second travel rail arranged to extend in a second direction at an angle with respect to the first travel rail,
wherein the rod body is in slidable connection with the second travel rail; and
wherein the second travel rail is in slidable connection at a bottom portion thereof with the first travel rail.

10. The repairing apparatus according to claim 8, wherein the movable assembly further comprises an image acquisition device provided on the movable support.

11. The repairing apparatus according to claim 8, further comprising a drive component which is arranged to be connected electrically with the movable assembly and configured to control the movable assembly to move in the first direction.

12. The repairing apparatus according to claim 1, further comprising a fixation table configured to fix the display substrate, with at least one fixation component being provided on the fixation table and configured to fix the display substrate.

13. The repairing apparatus according to claim 1, wherein the at least one fixation component comprises a plurality of the adsorption components.

14. The repairing apparatus according to claim 11, wherein the drive component is further configured to control the movable assembly to move in the second direction.

15. The repairing apparatus according to claim 9, wherein the first direction is substantially perpendicular to the second direction.

16. The repairing apparatus according to claim 15, wherein the first direction is a lengthwise direction of the movable table.

17. The repairing apparatus according to claim 1, wherein the adsorption component is a suction disc.
